(19) United States
(12) Patent Application Publication
(10) Pub. No.: US 2003/0213124 A1
(43) Pub. Date: Nov. 20, 2003

(54) Method for packaging image sensors

(76) Inventors: Jason Chuang, Hsinchu Hsien (TW); Jichen Wu, Hsinchu Hsien (TW); Jachson Hsieh, Hsinchu Hsien (TW)

Correspondence Address: PRO-TECHTOR INTERNATIONAL SERVICES, 20775 Norada Court, Saratoga, CA, 95070-3018, US

(21) Appl. No.: 10/147,030

(22) Filed: May 15, 2002

(51) Int. Cl. H05K 3/30; H05K 13/00; B23P 17/00

(52) U.S. Cl. 29/854; 29/832; 29/417

(57) ABSTRACT

A method for packaging image sensors of the invention includes the steps of: providing a substrate formed with a plurality of zones, traces, and first long-holes penetrating through the substrate at a periphery of each zone, the zones being separated by the first long-holes; providing a frame layer placed on the substrate, the frame layer being formed with slots at positions corresponding to the zones of the substrate, and with second long-holes at positions corresponding to the first long-holes of the substrate; placing a plurality of photosensitive chips in each of the zones of the substrate and within the slots, respectively; electrically connecting the plurality of photosensitive chips to the substrate; placing a plurality of transparent layers above the slots of the frame layer to cover the photosensitive chips, respectively; and cutting along the first long-holes of the substrate and the second long-holes of the frame layer to form a plurality of image sensors. Accordingly, the manufacturing cost can be lowered and the production yield can be increased.

### BACKGROUND OF THE INVENTION

1. Field of the Invention

The invention relates to a method for packaging image sensors, and more specifically to a convenient method for packaging image sensors with a high production yield.

2. Description of the Related Art

Referring to FIGS. 1 and 2, a conventional package structure for photosensitive chips is manufactured according to the following steps. First, a substrate 10, on which traces 12 are formed to define a plurality of zones 17, is provided. Then, a plurality of photosensitive chips 13 is arranged in the plurality of zones 17. Next, a frame layer 14 formed with a plurality of slots 16 corresponding to the traces 12 is adhered onto the substrate 10 via an adhesive layer 15. At this time, the photosensitive chips 13 on the substrate 10 are exposed via the slots 16. Then, a plurality of wires 18 is provided to electrically connect the photosensitive chips 13 to the substrate 10. Next, the substrate 10 is cut into package bodies each including the frame layer 14, as shown in FIG. 2. Then, as shown in FIG. 3, a single package body is placed within a jig 22, and a zone for receiving a transparent glass 20 is defined. Next, the transparent glass 20 covers the frame layer 14 to finish the package processes of the photosensitive chips 13.

As shown in FIG. 4, the backside of the substrate 10 is formed with output traces 23 connecting to the traces 12, respectively. In addition, the output traces 23 in adjacent zones are connected. When plural individual package bodies are cut along the scribing lines 24, the output traces 23 at adjacent zones can be separated.

The conventional image sensor has the following drawbacks.

That is, when plural individual package bodies are cut, the output traces 23 of the substrate 10 may often be damaged. In addition, since the substrate 10 and the frame layer 14 are bonded by the adhesive layer 15, the adhesive layer 15 may overflow to cover the output traces 23 during the cutting process, thereby adversely influencing the yield of the image sensor.

In view of the above-mentioned problems, it is an important subject of the invention to provide a method for packaging the image sensor to improve the drawbacks of the conventional image sensor and to make the image sensor more practical.

### SUMMARY OF THE INVENTION

It is therefore an object of the invention to provide a method for packaging image sensors, wherein the production yield of the image sensors is increased to lower the package cost.

To achieve the above-mentioned object, the method for packaging image sensors of the invention includes the steps of:

providing a substrate formed with a plurality of zones, traces, and first long-holes penetrating through the substrate at a periphery of each zone, the zones being separated by the first long-holes;

providing a frame layer placed on the substrate, the frame layer being formed with slots at positions corresponding to the zones of the substrate, and with second long-holes at positions corresponding to the first long-holes of the substrate;

placing a plurality of photosensitive chips in each of the zones of the substrate and within the slots, respectively;

electrically connecting the plurality of photosensitive chips to the substrate;

placing a plurality of transparent layers above the slots of the frame layer to cover the photosensitive chips, respectively; and

cutting along the first long-holes of the substrate and the second long-holes of the frame layer to form a plurality of image sensors.

According to the invention, the manufacturing cost can be lowered and the production yield can be increased.

### BRIEF DESCRIPTION OF THE DRAWINGS

FIG. 1 is an exploded view showing a conventional image sensor.

FIG. 2 is a first schematic illustration showing the cross-section of the conventional image sensor.

FIG. 3 is a second schematic illustration showing the cross-section of the conventional image sensor during the manufacturing processes.

FIG. 4 is a backside view showing the conventional substrate.

FIG. 5 is an exploded view showing the image sensor of the invention.

FIG. 6 is a backside view showing the substrate of the invention.

FIG. 7 is a pictorial view showing the combination of the image sensors of the invention.

FIG. 8 is a schematically cross-sectional view showing the image sensor of the invention.

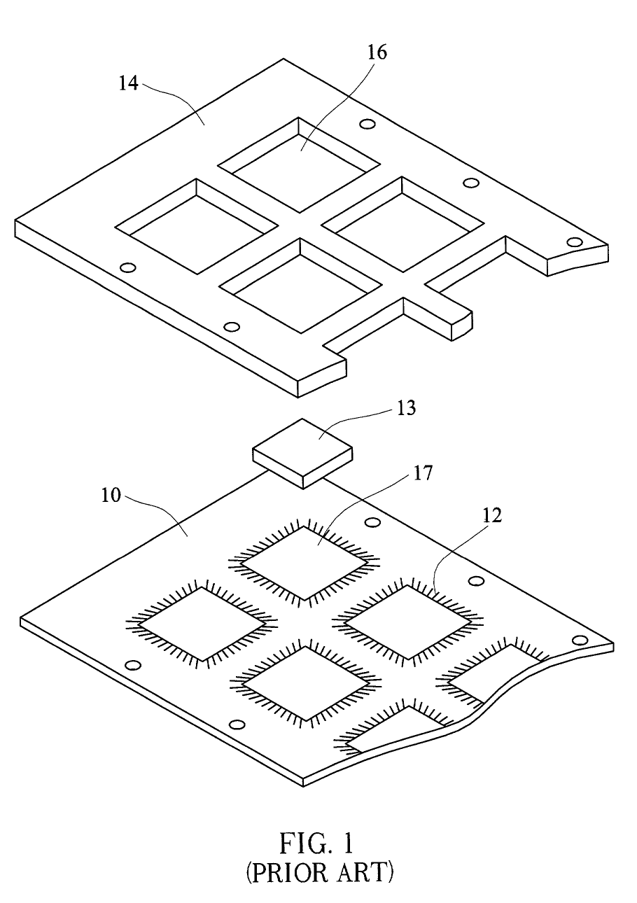

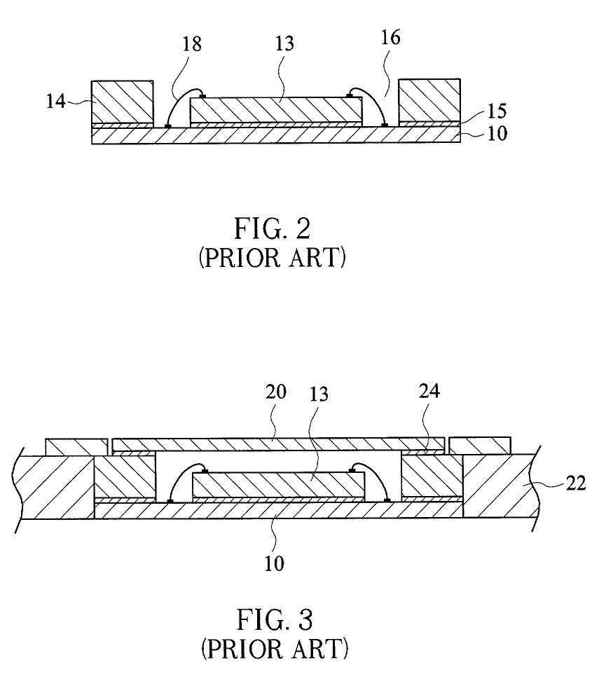

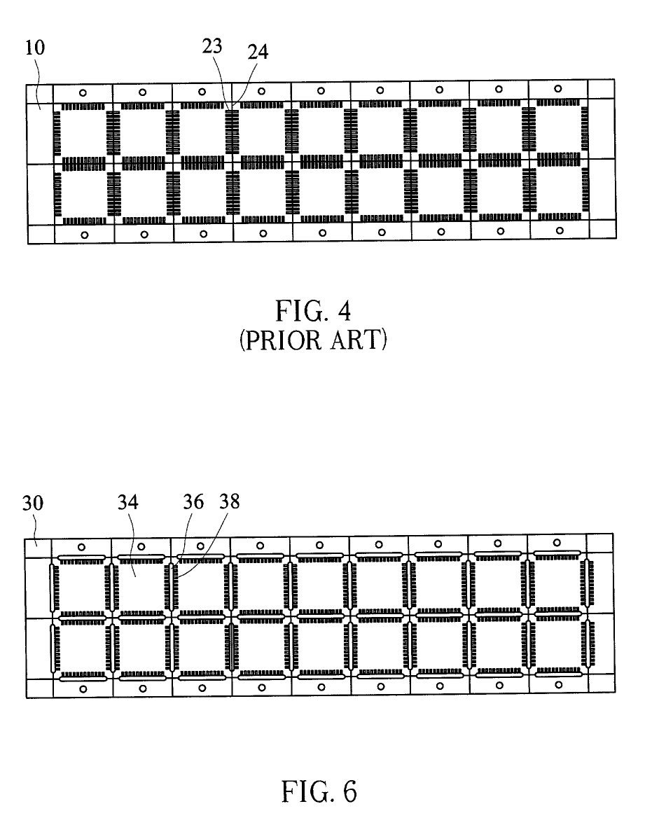

### DETAILED DESCRIPTION OF THE INVENTION

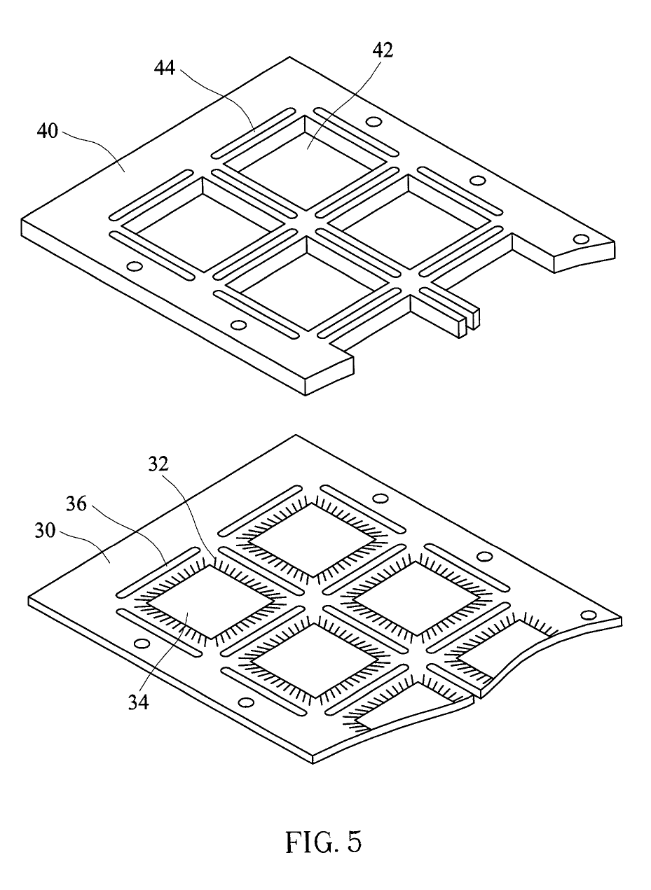

Referring the FIG. 5, the method for packaging the image sensor of the invention includes the steps described as follows.

First, a substrate 30 formed with plural zones 34 and traces 32 at the periphery of each zone 34 is provided. The substrate 30 is further formed with first long-holes 36 penetrating the substrate 30 at the periphery of each zone 34 such that the adjacent zones 34 are separated from each other by the first long-holes 36. Referring also to FIG. 6, the substrate 30 includes output traces 38, which are formed at the periphery of each zone 34 and connected to the traces 32. The output traces 38 between the adjacent zones 34 are separated by the first long-holes 36.

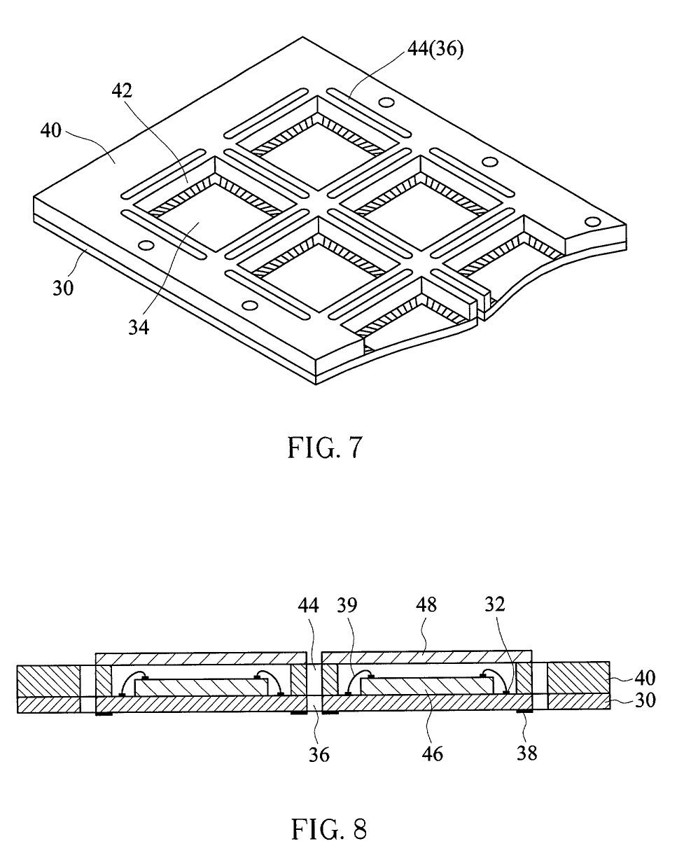

Next, a frame layer 40 is adhered onto the substrate 30 by an adhesive layer. The frame layer 40 is formed with slots 42 at positions corresponding to each zone 34 of the substrate 30. The frame layer 40 is further formed with second long-holes 44 at positions corresponding to each first long-hole 36 of the substrate 30. It should be noted that the second long-holes could also be eliminated without influencing the formation of the image sensors. Referring also to FIG. 7, when mounting the frame layer 40 on the substrate 30, the zones 34 of the substrate 30 are exposed via the slots 42, and the second long-holes 44 are stacked above and communicated with the first long-holes 36, respectively.

Then, referring to FIG. 8, a plurality of photosensitive chips 46 are placed in each zone 34 of the substrate 30 and within each slot 42 and exposed via each slot 42.

Subsequently, a plurality of wires 39 is provided for electrically connecting the photosensitive chips 46 to the traces 32 of the substrate 30. Accordingly, signals from the photosensitive chips 46 may be transferred to the traces 32, and then to the output traces 38 on the backside of the substrate 30.

Next, a plurality of transparent layers 48, each of which may be a piece of transparent glass, is placed above each slot 42 of the frame layer 40 to cover each photosensitive chip 46, which may receive optical signals passing through the transparent layer.

Then, the image sensor assembly having packaged photosensitive chips is cut into plural individual package bodies along the first long-holes 36 and the second long-holes 44.

In another embodiment, it is also possible to put the individual package body into a jig (not shown) to position the region for the transparent layer 48 to be placed. Then, the transparent layer 48 may be precisely placed to cover the frame layer 40.

The method of the invention has the following advantages.

1. Since the output traces 38 at adjacent zones 34 of the backside of the substrate 30 are separated, in advance, by the first long-hole 36, the output traces 38 are free from being damaged during the cutting process along the first long-holes 36. Thus, the production yield can be effectively increased.

2. Since the first long-holes 36 and the second long-holes 44 are formed, in advance, on the substrate 30 and the frame layer 40, respectively, it is convenient and time-saving to cut the substrate 30 into plural individual package bodies. Furthermore, it is also possible to separate each package body by human hands.

While the invention has been described by way of an example and in terms of a preferred embodiment, it is to be understood that the invention is not limited to the disclosed embodiment. To the contrary, it is intended to cover various modifications. Therefore, the scope of the appended claims should be accorded the broadest interpretation so as to encompass all such modifications.

What is claimed is:

1. A method for packaging image sensors, comprising the steps of:
providing a substrate formed with a plurality of zones, traces, and first long-holes penetrating through the substrate at a periphery of each zone, the zones being separated by the first long-holes;
providing a frame layer placed on the substrate, the frame layer being formed with slots at positions corresponding to the zones of the substrate, and with second long-holes at positions corresponding to the first long-holes of the substrate;
placing a plurality of photosensitive chips in each of the zones of the substrate and within the slots, respectively;
electrically connecting the plurality of photosensitive chips to the substrate;
placing a plurality of transparent layers above the slots of the frame layer to cover the photosensitive chips, respectively; and
cutting along the first long-holes of the substrate and the second long-holes of the frame layer to form a plurality of image sensors.

2. The method according to claim 1, wherein the frame layer is adhered to the substrate by an adhesive layer.

3. The method according to claim 1, wherein each of the transparent layers is a piece of transparent glass.

4. The method according to claim 1, wherein the photosensitive chips are electrically connected to the substrate by a plurality of wires.

5. A method for packaging image sensors, comprising the steps of:
providing a substrate formed with a plurality of zones, traces, and first long-holes penetrating through the substrate at a periphery of each zone, the zones being separated by the first long-holes;
providing a frame layer placed on the substrate, the frame layer being formed with slots at positions corresponding to the zones of the substrate;
placing a plurality of photosensitive chips in each of the zones of the substrate and within the slots, respectively;
electrically connecting the plurality of photosensitive chips to the substrate;
placing a plurality of transparent layers above the slots of the frame layer to cover the photosensitive chips, respectively; and
cutting along the first long-holes of the substrate to form a plurality of image sensors.

6. The method according to claim 5, wherein the frame layer is adhered to the substrate by an adhesive layer.

7. The method according to claim 5, wherein each of the transparent layers is a piece of transparent glass.

8. The method according to claim 5, wherein the photosensitive chips are electrically connected to the substrate by a plurality of wires.
